(19) United States
(12) Patent Application Publication
(10) Pub. No.: US 2009/0140435 A1
(43) Pub. Date: Jun. 4, 2009

(54) SEMICONDUCTOR INTEGRATED CIRCUIT DEVICE AND A METHOD OF PROTOTYPING A SEMICONDUCTOR CHIP

(75) Inventor: David Lynch, Ballyjamesduff (IE)

Correspondence Address: FAEGRE & BENSON LLP;PATENT DOCKETING - INTELLECTUAL PROPERTY, 2200 WELLS FARGO CENTER, 90 SOUTH SEVENTH STREET, MINNEAPOLIS, MN, 55402-3901, US

(73) Assignee: GloNav Limited, Dublin (IE)

(21) Appl. No.: 11/966,750

(22) Filed: Dec. 28, 2007

(30) Foreign Application Priority Data
Nov. 30, 2007 (IE) 2007/0870

(51) Int. Cl. H01L 23/48; H01L 21/4763; H01L 21/02

(52) U.S. Cl. 257/774; 438/637; 438/4; 257/E23.168; 257/E21.597

(57) ABSTRACT

In a semiconductor integrated circuit device comprising a semiconductor chip having a number of conductor layers and a number of via layers between the conductor layers, a routing matrix is provided in a small area of the chip to act as a revision number register. The routing matrix includes a matrix block having, in each metal layer of the chip, conductor tracks, the tracks in each metal layer running in a respective direction different from the direction of the tracks in the adjacent metal layers so that the tracks of each consecutive pair of metal layers cross over each other. In each via layer between consecutive metal layers, the matrix block includes selectively placed vias interconnecting the tracks in the adjacent metal layers on each side of the respective via layer. The tracks in each metal layer comprise source tracks and output tracks, the source tracks being coupled respectively to logic level sources of opposite polarity and the output tracks providing register outputs which carry a high or low logic level depending on their individual connections in the routing matrix block to the supply lines. The arrangement is such that when a change in the primary circuits of the chip is required, a new revision number output can be generated by altering the interconnections of the conductor tracks of the routing matrix only in the respective metal layer or via layer which has been changed in the primary circuits.

### FIELD OF THE INVENTION

This invention relates to a semiconductor integrated circuit device including an arrangement of conductors generating a revision number output. The invention also includes a method of prototyping in which successive chip implementations have different respective identifying revision numbers coded on the chip.

### BACKGROUND OF THE INVENTION

Most digital integrated circuit devices contain circuit elements that produce a revision number output for identifying the version of a chip. Typically, this revision number can be accessed through the device JTAG port using the ID CODE instruction, where available, or through a software read of a dedicated internal revision register.

The revision number is typically hard-coded into the device during the design stage of production, and the individual bits in the hard-coded register are connected to one of two supply busses (VDD-high or VSS-low) during the chip “synthesis” and “place and route” operations. The physical routing from the VDD or VSS rail to the hard-coded register bits using a chip routing tool can be done on any of the metal routing layers.

If a fault is discovered after the chip has been taped-out and manufactured, it may be necessary to perform a modification or “engineering change order” (ECO) on the design in order to rectify the fault. If the design fault can be rectified easily, it may be possible to make the change using a small number of the metal and via layers of the device. This reduces the cost of re-manufacturing considerably in comparison to an all-layer change.

It is desirable to update the revision number whenever an ECO has been made after tape-out, each updated revision number reflecting the change that is made in order to differentiate the new version of the device from previous versions. However, if the revision number bits have been connected to the VSS or VDD rail on different metal layers than those that have been modified during the ECO, then this is not possible without incurring the extra cost of further layer changes.

U.S. Pat. No. 5,787,012 teaches an integrated circuit in which the value of the revision number can be changed by altering connections in a first metal layer or a second metal layer according to whether corresponding changes are made in the first or second metal layer. Logic circuitry combines circuit identification signals from the two layers to produce a revision number.

It is a feature of the invention to provide a more flexible solution to a revision number indication in successive semiconductor chip versions.

### SUMMARY OF THE INVENTION

According to a first aspect of the invention, a semiconductor integrated circuit device comprises a semiconductor chip having a plurality of conductor layers and via layers between the conductor layers, wherein the layers together include an arrangement of conductors generating a revision number output, and the arrangement includes conductors in all of said conductor and via layers. It is preferred that the conductors of the conductor arrangement in each conductor layer comprise at least two parallel conductor tracks. More particularly, the preferred arrangement of conductors includes, in each pair of consecutive conductor layers, at least one first conductor track in one of the conductor layers of said each pair and at least one second conductor track in the other conductor layer of said each pair, the first conductor track crossing over the second conductor track in said each pair. Typically, the arrangement further comprises at least one via in the via layer between the above-mentioned pair of conductor layers, which via interconnects said first conductor track with a said second conductor track.

In this way, the arrangement of conductors may be such as to comprise a revision number matrix with the first conductor tracks oriented in one direction and the second conductor tracks oriented in another direction, typically perpendicular to the first direction.

By connecting each of the conductor tracks either to a high voltage potential conductor in the chip, or a lower voltage potential conductor, the track can be arranged to carry a high voltage or a low voltage according to revisions made in the respective layer of the chip. Connections to each of the high and low voltage potential conductors from the conductor tracks of the conductor arrangement revision number matrix may be made by stacked vias.

The most efficient use of space is typically achieved by forming the arrangement of conductors or revision number matrix in portions of the area of each conductive layer and via layer which are stacked so as to be substantially in registry with each other.

The revision number matrix has a series of outputs on the different metal and via layers of the chip. Whenever a revision is made, the connection of a conductor of the matrix in one of the layers in which the revision is made is altered so that, when the chip is powered up, the logic levels on the revision number matrix outputs together uniquely represent the version of the chip. The revision number of each individual mask layer can be determined from the revision number logic levels on the matrix outputs.

According to a second aspect of the invention, a method of prototyping a semiconductor chip for a semiconductor integrated circuit comprises producing successive chip implementations each having a respective identifying revision number which is coded on the chip by an arrangement of conductors in all of the conductor and via layers of the chip, wherein the production of each implementation by modifying the design of a previous such implementation includes altering said arrangement of conductors only in each conductor or via layer in which a circuit alteration is being made in the modification.

The invention will be described below by way of example with reference to the drawings.

### BRIEF DESCRIPTION OF THE DRAWINGS

In the drawings:

FIG. 1 is a block diagram of circuitry for generating a revision number and which represents a portion of a semiconductor chip in accordance with the invention;

FIG. 2 is a conductor layout diagram showing five layers of the circuitry for generating a revision number; and

FIG. 3 is a conductor layout diagram corresponding to that of FIG. 3 for a different version of the semiconductor chip.

### DETAILED DESCRIPTION OF THE PREFERRED EMBODIMENT OF THE INVENTION

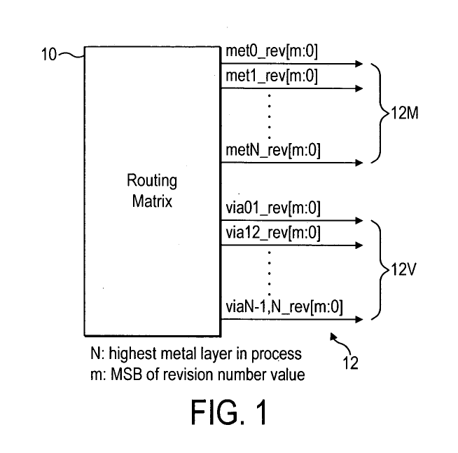

In an semiconductor integrated circuit device, in accordance with the invention, having a semiconductor chip, a discrete area of the chip, representing a small part of the total area, is occupied by a routing matrix block for generating a revision number output on a plurality of output connections or lines. The routing matrix is shown in block diagram form in FIG. 1. The matrix 10 encompasses all metal and via layers of the semiconductor chip. For the purposes of the diagram of FIG. 1, the chip is regarded as having N metal layers, layer N being the highest metal layer. The revision number output is generated on a number of output lines 12 which are grouped as metal layer output lines 12M and via output lines 12V, there being N×B metal layer output lines met1_rev[m:0] to metN_rev[m:0], each of the lines 12M and 12V represent B output lines in practice, where B is the number of bits of a revision number generated for each metal or via layer. The nomenclature [m:0] is a vectorial representation which indicates a number having m as its most significant bit end and 0 as the starting value. In the labels associated with each output line in FIG. 1, m represents the most significant bit (MSB) of the revision number value available from each layer.

For reasons which will become clear below, the revision number output value generated by the routing matrix 10 is B×(2N−1) bits wide, B being the number of output bits per metal/via layer, and N being the number of metal layers in the process. Thus, for example, where a semiconductor chip has seven metal layers, and two revision number bits are provided per metal layer, the resulting revision number outputted on lines 12 is 26 bits in length. In this case, therefore, the revision number may be expressed as:

rev_num[25:0]={met7_rev[1:0], . . . , met1_rev[1:0], via67_rev[1:0], . . . via12_rev[1:0]}

It will be appreciated that a chip having N metal layers typically has N−1 via layers. Thus, in FIG. 1, the via output lines (bearing in mind that each represents B actual output lines in practice) are designated via12_rev[m:0], via23_rev[m:0] . . . viaN−1, N_rev[m:0].

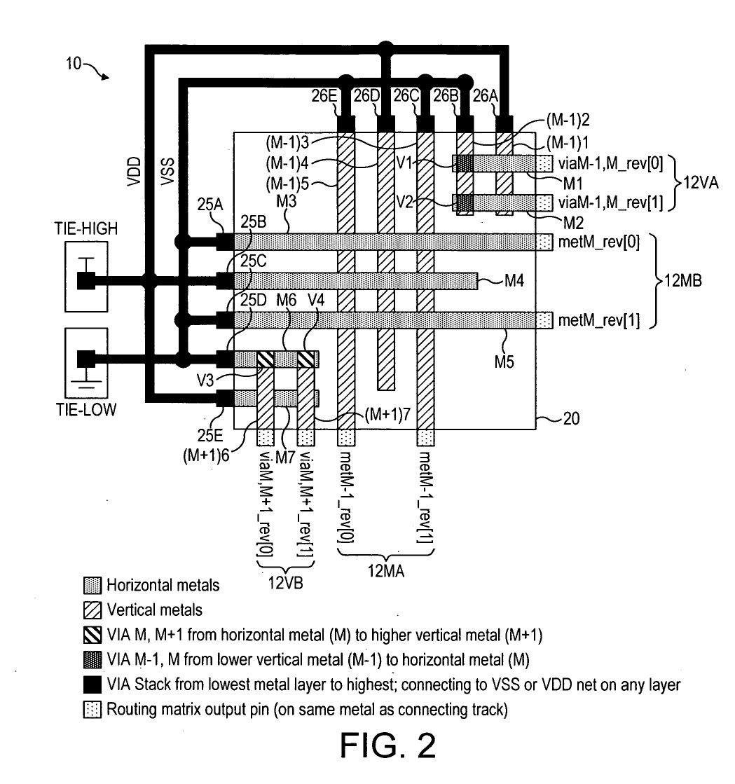

The routing matrix 10 will now be described in more detail with reference to FIG. 2. In effect, FIG. 2 is a plan view of a small part of the semiconductor chip referred to above as having a routing matrix as shown in FIG. 1. The routing matrix contains a small custom-layout matrix block 20. Associated with the matrix block 20 are supply line nets VSS and VDD which are connected to standard cell library tie-low and tie-high cells, as shown, the latter being provided to minimise the possibility of damage to the chip. The supply nets VDD and VSS provide high and low logic level inputs, respectively, for a number of tracks in each metal layer of the matrix block 20. Some of these tracks in each layer are connected to respective revision number output lines 12MA, 12MB, 12VA, and 12VB (hereinafter referred to as “output pins” in the description of the routing matrix block), the conductor tracks in each layer, together with vias, interconnecting those tracks with the tracks on the metal layers immediately above and below to determine the logic levels on the output pins 12MA, 12MB, 12VA and 12VB according to the pattern of the tracks and the interconnections between them.

It will be seen from FIG. 2 that, in each layer, some of the tracks are connected to the VDD net, and others to the VSS net. Some are connected solely to the output pins.

It will be understood that the layout diagram of FIG. 2 shows conductor tracks on only five layers of a semiconductor chip having N metal layers and N−1 via layers between the metal layers. The five layers are a middle metal layer M, a lower metal layer M−1, the via layer (M−1, M) between the lower and middle metal layers, an upper metal layer M+1 and, lastly, the upper via layer (M, M+1) lying between the middle metal layer and the upper metal layer.

Still referring to FIG. 2, including the shading key, the middle metal layer of the matrix block 20 has seven parallel metal tracks M1-M7 oriented in a first direction, in this case horizontally in the diagram. The tracks M1-M7 are arranged in three groups comprising a first pair of tracks M1 and M2 which form part of a lower via circuit and which are connected to respective via circuit output pins 12VA. A middle group of tracks M3-M5 includes two tracks M3 and M5 which, in this configuration of the matrix block 20, extend from one side of the block to the other, i.e. from via stacks 25A and 25C connected to the VSS net to metal layer output pins 12MB on the other side of the block. A third track M4 of the middle group, located between and close to the other tracks M3 and M5 of the group is attached to an opposite polarity via stack 25B at the side of the matrix block so as to be connected to the VDD net. However, this intermediate track M4 terminates short of the opposite side of the block 20 since its purpose is to act as a conductor to which portions of the outer tracks M3 and M5 of the group can be connected, as will be described below, in order to reverse the logic level on the associated output pins.

The third group of horizontal tracks M6 and M7 form part of an upper via circuit. These tracks extend to only one edge of the matrix block 20, where they are connected respectively to via stacks 25D and 25E of opposing polarity (owing to their connection to the VSS and VDD nets respectively).

A feature of this embodiment of the invention is that conductor tracks in neighbouring metal layers run in different directions. It follows, therefore, that, for instance, in a chip having seven metal layers, the layers having even layer numbers (M=2,4,6) have tracks running in one direction, e.g. horizontal in FIG. 2, whereas layers having odd layer numbers (M=1,3,5,7) have tracks running in a second direction, i.e. preferably perpendicularly to the tracks of the even-numbered layers (vertical in FIG. 2). This allows the tracks in each pair of neighbouring metal layers to cross over each other in the form of a grid so that interconnections can be made selectively by way of vias between the tracks of the mutually adjacent metal layers.

Referring again, therefore, to FIG. 2, metal layer M−1 has groups of vertically oriented tracks (M−1)1 to (M−1)5 running underneath the tracks of the metal layer M. In the diagram of FIG. 2, only two groups of such vertically oriented tracks are shown. In the general case, there are three groups of seven tracks arranged in a manner analogous to the arrangement of the tracks in the layer M. A first group of tracks in metal layer M−1, formed by tracks (M−1)2 and (M−1)1 run underneath the via-circuit tracks M1 and M2 of metal layer M and are connected at an upper edge of the matrix block 20 to opposite polarity logic levels, i.e. the VDD net and VSS net respectively by stacked vias 26A and 26B. As indicated by the shading key in FIG. 2, it will be seen that the via layer (M−1, M) contains conductive vias at each location where the conductor tracks M1 and M2 of the via circuit overlap, respectively, one or other of the conductor tracks (M−1)1 and (M−1)2 of the lower metal layer. Accordingly, with these vias V1 and V2 forming part of a via circuit with the respective conductor tracks of the middle and lower metal layers, the output pins 12VA at the ends of the middle layer metal tracks M1 and M2 are selectively coupled to the VDD net or the VSS net, respectively, depending on the locations of the vias V1 and V2.

The second group of conductor tracks in metal layer M−1, i.e. conductor tracks (M−1)3 to (M−1)5, are configured in the same way as the middle group of tracks M3 to M5 of metal layer M, and are similarly connected to the VDD net and VSS net and to a pair of metal layer output pins 12MA.

Also visible in FIG. 2 are two conductor tracks (M+1)6, (M+1)7, which are also vertically oriented. These tracks lie over the tracks M6 and M7 of the middle metal layer and are connected to via circuit output pins 12VB. As in the case of the via circuit described above having vias in the lower via layer (M−1, M), the upper via layer (M, M+1) between the middle and upper metal layers has vias V3 and V4 located at respective intersections (locations of overlap) between the via circuit tracks (M+1)6, (M+1)7 of the upper layer and metal tracks M6 and M7 of the middle layer so that the via circuit output pins 12VB are selectively coupled, respectively, to the VDD net or VSS net according to the locations of the two vias V3 and V4. As in the case of metal layer M−1, only some of the conductor tracks of the upper metal layer M+1 are shown in FIG. 2 for reasons of clarity.

It will be appreciated that it is not necessary for the conductor tracks linking the supply nets VDD and VSS with the metal layer outputs 12MA and 12MB to be centrally located in the matrix block 20, and for the conductor tracks and vias forming the via-circuits to be located in corners or near the edges of the matrix block 20. However, such an arrangement is chosen for compactness. Again, for compactness, the conductor tracks of the other layers of the matrix block are located in registry with the equivalent conductor tracks of the lower and upper layers M−1, M+1 to save area. Thus, all horizontal routing tracks (e.g. for layers 2, 4 and 6 in a 7 metal layer chip) can be formed on top of each other and, similarly all vertical routing tracks (for layers 1, 3, 5 and 7) are formed on top of each other. Where tracks in any given layer connect directly to output pins, they are connected to output pins on the same layer, and these output pins are also stacked on top of each other. This means, for example, that the met2_rev[0] output is directly under the met4_rev[0] and met6_rev[0] output pins.

The via stacks 25A-25E and 26A-26E each extend from the lowest metal layer to the highest metal layer and form matrix block inputs allowing the VDD and VSS nets to be connected in any routing layer.

In this embodiment, all output pins have an initial default connection to the VSS net. Thus, the metal revision numbers (met1_rev[1:0], met2_rev[1:0], up to met7_rev[1:0]) connect directly to the VSS net.

The via circuit outputs 12VA (via M−1, M rev[1:0]) connect to the VSS net through two pairs of metal tracks M1, M2, (M−1)1, (M−1)2 joined by the interconnecting vias V1 and V2. Thus, in a real example, the output pin via23_rev[0] is connected to a track on metal layer 3, which is, in turn, connected to a track in metal layer 2 running to the VSS input net by a via in via layer 23.

It should be noted that the routing matrix 20 described above with reference to FIG. 2 yields two output bits per metal layer or via layer. This allows for up to three revision values to be made per layer. If more bits are required, the matrix can be scaled up accordingly by adding extra conductor tracks in each layer, as will be understood by those skilled in the art.

As stated above, the configuration of the conductor tracks and the location of the vias in the routing matrix block 20 described with reference to FIG. 2 represent an initial or default configuration. This is the configuration of the routing matrix in the initial version of the chip. If a fault is discovered in the primary circuits of this version of the chip, requiring a change in one of the metal or via layers, the conductor pattern in the same layer, and only that same layer, of the routing matrix is changed. In other words, alterations are made to the electronic mask file for only the layer which is being changed. This means that the number of new masks for changes is minimised. Only this minimum number of masks needs to be sent to the chip fabricator for making the next version of the chip.

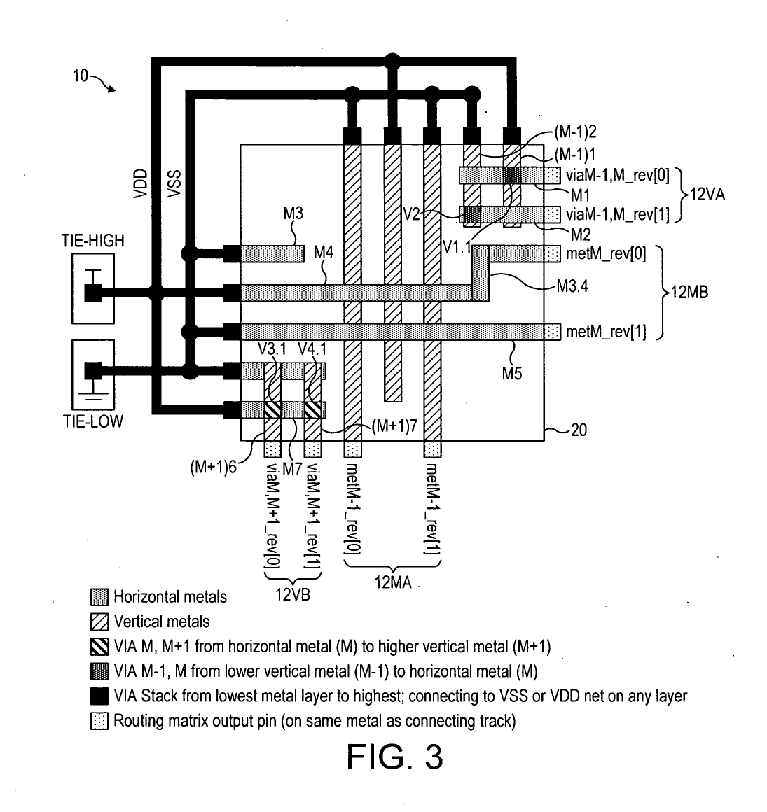

The manner in which the revision number is altered to record a change will be described with reference to FIG. 3.

When an engineering change order (ECO) is made to metal layer M of the chip, the binary number outputted on the output pins 12MB is incremented by 1. That is, the metM_rev[1:0] output is changed from “00” to “01” (i.e. a two-bit binary value changing from “00” to “01”). This is achieved by breaking one of the conductor tracks M3 and M5, interconnecting the VSS net to the output pins 12MB, and instead connecting that output pin to the central conductor track M4 of the group, which, as noted before, is connected to the VDD supply net, by the link M3.4 in FIG. 4. For the purposes of this description, this ECO is referred to as ECO1. Summarizing the recording of ECO1, the metM_rev[0] track is disconnected from VSS and connected instead to VDD so that the metM_rev[1:0] 2-bit binary output is now “01” rather than “00”.

If, subsequently, another ECO is required, resulting in a second version of the chip, and if this second ECO, ECO2, is made in a via layer, a change is made in the routing matrix block 20 in the same via layer. In other words, as in the case of ECO1, the only layers of the metal and via layers in the routing matrix block which are changed are the layer or layers in which the primary circuits of the chip are changed. Therefore, the binary number represented by the output pins of the via circuit corresponding to the changed via layer is incremented from 00 to 01. This is done by manually removing one of the vias, in this case, via V1, in the respective mask, and replacing it with a new via, via V1.1 (see FIG. 4) so as to connect the conductor track in the neighbouring metal layer, which track is connected to the via circuit output pin, to the supply net of opposite plurality, in this case, the VDD net. More particularly, referring to FIGS. 2 and 3, the revision output via M−1, M_rev[1:0] has been changed from 00 to 01. Summarizing the recording of ECO2, the via V1 is moved to become via V1.1 to connect viaM−1,M_rev[0] to VDD so that the viaM−1,M_rev[1:0] 2-bit binary output is now 01 instead of 00.

If, subsequently, an Nth ECO, ECON, is required, for instance, in the upper via layer, which corresponds to the third such ECO to this layer, V3 can be removed from the respective mask and a new via, V3.1, is added to alter the polarity of the respective output pins 12VB associated with the via circuit for the upper via layer. In other words, the viaM,M+1_rev[1:0] is incremented from the 2-bit binary value “10” to “11”, as part of the ECON, signifying that the via M, M+1 mask layer is on its third ECO. Summarizing, in the recording of ECON, via V3 is moved to connect via M, M+1_rev[1:0] to VDD so that the viaM,M+1_rev[1:0] output is now the 2-bit binary value “11” rather than “10”.

What is claimed is:

1. A semiconductor integrated circuit device comprising:
a semiconductor chip having a plurality of conductor layers and via layers between the conductor layers, wherein said layers together include an arrangement of conductors generating a revision number output, and the arrangement includes conductors in all of said conductor and via layers.

2. The device according to claim 1, wherein the conductors of the arrangement in each conductor layer comprise at least two parallel conductor tracks.

3. The device according to claim 1, wherein the arrangement of conductors includes, in each pair of consecutive conductor layers, at least one first conductor track in one of the conductor layers of said each pair and at least one second conductor track in the other conductor layer of said each pair, the first conductor track crossing over the second conductor track in said each pair, and wherein the arrangement further comprises, in the via layer between said each pair of conductor layers, at least one via interconnecting said first conductor track with said second conductor track.

4. The device according to claim 3, wherein the arrangement of conductors comprises a revision number matrix, the or each first conductor track being oriented in a first direction and the or each second conductor track being oriented in a second direction.

5. The device according to claim 1, wherein the arrangement of conductors comprises a revision number matrix, and wherein each pair of consecutive conductor layers and the via layer therebetween include a via-change registering circuit comprising, in one of the conductor layers a pair of source tracks arranged to carry different source signals, in the other of the conductor layers at least one output track that crosses over the source tracks, and, in the via layer, a via for each respective output track, each such via linking the respective output track with a selected one of the source tracks.

6. The device according to claim 1, wherein each of the conductor tracks is connected to either a high voltage potential conductor or a low voltage potential conductor.

7. The device according to claim 6, wherein said connections to each of the high and low voltage potential conductors are made by stacked vias.

8. The device according to claim 1, wherein a portion of an area of each conductor layer and via layer is allocated to said arrangement of conductors, all of the area portions being stacked so as to be substantially in registry with each other.

9. A method of prototyping a semiconductor chip for a semiconductor integrated circuit, said method comprising:
producing successive chip implementations each having a respective identifying revision number which is coded on the chip by an arrangement of conductors in all of the conductor and via layers of the chip, wherein the production of each implementation, by modifying the design of a previous such implementation, includes altering said arrangement of conductors only in each conductor or via layer in which a circuit alteration is being made in said modification.

10. The method according to claim 9, wherein the production of each implementation, in which a selected via layer is modified, includes removing a via in the selected via layer in said arrangement of conductors to disconnect an output track in a metal layer on one side of the selected via layer from a signal source track in the metal layer on the other side of the selected via layer.

11. The method according to claim 10, including replacing the removed via with a via connecting said output track to another signal source track in the metal layer on said other side of the via layer.

12. The semiconductor device according to claim 1, wherein
said arrangement of conductors is configured to be altered, for each conductor or via layer including a circuit modification, to generate said revision number output.
